(19) United States
(12) Patent Application Publication
(10) Pub. No.: US 2025/0120029 A1
(43) Pub. Date: Apr. 10, 2025

(54) DISPLAY APPARATUS AND VEHICLE INCLUDING THE SAME

(71) Applicant: LG Display Co., Ltd., Seoul (KR)

(72) Inventor: Byeongjo MIN, Paju-si (KR)

(21) Appl. No.: 18/899,753

(22) Filed: Sep. 27, 2024

(30) Foreign Application Priority Data
Oct. 4, 2023 (KR) 10-2023-0131557

(51) Int. Cl. H05K 5/03; B60K 35/50; H10K 59/80; H10K 102/00

(52) U.S. Cl. CPC H05K 5/03; B60K 35/50; H10K 59/873; H10K 59/872; H10K 2102/311

(57) ABSTRACT

Disclosed is a display apparatus mounted on a vehicle that prevents head injury to a driver or a passenger caused by the display apparatus in event of a vehicle collision, and vehicle including the same. To this end, the display apparatus has a structure in which a back cover coupled to a cover glass module including a display panel is fixed to a dashboard of the vehicle through a mounting part made of flexible rubber. Therefore, the mounting part that fixes the back cover is made of a flexible rubber material. A content of metal or acrylic material added to the rubber material is controlled to achieve the mounting part which absorbs a shock and, at the same time, prevents decrease in a supporting ability of the mounting part.

### CROSS-REFERENCE TO RELATED APPLICATION

This application claims priority from Korean Patent Application No. 10-2023-0131557 filed on Oct. 4, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display apparatus, and more specifically, to a display apparatus mounted on a vehicle.

### Description of Related Art

Generally, a display apparatus for a vehicle is equipped with a display module on a vehicle's dashboard to provide convenience to a user such as a driver and to help ensure safe driving of the vehicle.

This vehicle display module has a structure in which a back cover combined with a cover glass module and a mounting part are integrated into a single body made of the same material in an injection molding manner, and the single body is coupled to the dashboard using a bolt.

As the back cover and the mounting part are formed to the integrated structure, in the event of a vehicle collision, the driver or the passenger may hit the hard back cover and suffer a head injury.

### BRIEF SUMMARY

In order to minimize the injury to the drivers and the passenger in the event of a vehicle collision, a display apparatus that may meet a head impact criterion (HIC) required by regulations is required.

Accordingly, the inventor of the present disclosure have invented a display apparatus installed on a vehicle in which the back cover and the mounting part are separately manufactured, and the mounting part is made of a flexible material to prevent head injury in the event of a vehicle collision, and thus the mounting part plays a damping role in the event of a vehicle collision, thereby meeting the head impact criterion (HIC) and reducing the impact to prevent head injuries.

A purpose according to an embodiment of the present disclosure is to provide a display apparatus installed on a vehicle in which a mounting part that fixes the back cover is made of a flexible rubber material, and a content of a metal or an acrylic material within the rubber material is adjusted such that the mounting part plays a damping role capable of absorbing a shock and at the same time prevents a decrease in supporting ability of the mounting part.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display apparatus according to an embodiment of the present disclosure may be provided. The display apparatus may have a structure in which a back cover coupled to a cover glass module including a display panel is fixed to the dashboard through a mounting part made of flexible rubber.

Furthermore, in a display apparatus according to an embodiment of the present disclosure, a cover glass module includes a display panel, a scan driver supplies a scan signal to the display panel, a data driver supplies a data voltage to the display panel, a timing controller controls the gate driver and the data driver, a power supply supplies a high power voltage, a low power voltage, and an initialization voltage to the display panel, a back cover is coupled to a cover glass module to support the cover glass module, and a mounting part fixes the back cover, wherein the mounting part may include a damping portion made of a mixture of rubber and metal or a mixture of rubber and acrylic material.

According to an embodiment of the present disclosure, in the vehicle display apparatus, the back cover is fixed to the dashboard of the vehicle through the mounting part made of the flexible material, such that the mounting part acts as a damper to absorb shock and at the same time prevents decrease in the supporting ability of the mounting part.

Furthermore, according to an embodiment of the present disclosure, in installing the display apparatus on a vehicle, the display apparatus may be mounted to the dashboard through the mounting part including a damping portion, such that the HIC value is reduced by 45%, compared to a conventional case, in the event of an external impact.

Furthermore, according to an embodiment of the present disclosure, design change may be minimized in installing the display apparatus onto the vehicle. Thus, a resulting installation cost may be reduced.

Furthermore, when the display apparatus according to an embodiment of the present disclosure is installed on the vehicle, the display apparatus that can satisfy HIC-related safety regulations may be realized.

Furthermore, according to an embodiment in the present disclosure, in manufacturing the mounting part of the display apparatus using a rubber material, a content of each of the metal and the acrylic material in the rubber material may be controlled to control deceleration.

Furthermore, according to an embodiment of the present disclosure, occurrence of cracks in the display panel and damage to the display panel may be prevented due to the back frame made of the resin, thereby securing the rigidity of the display module and ensuring reliability thereof, such that quality of the display apparatus may be improved.

Furthermore, according to an embodiment of the present disclosure, occurrence of cracks in the display panel and damage to the display panel may be prevented due to the back frame made of the resin, thereby securing the rigidity of the display module, such that compressive rigidity of the bent portion of the display panel may be improved, and thus, a lifespan of the display panel may be increased.

Furthermore, according to an embodiment of the present disclosure, the back frame of the display apparatus may be made of the epoxy resin, thereby eliminating the air gap within the display module and securing the rigidity of the display module, thereby realizing a stable narrow bezel.

Furthermore, according to an embodiment in the present disclosure, when impact is applied to the bent portion of the display panel, occurrence of cracks in the display panel and damage to the display panel may be prevented due to the cushioning effect of the epoxy resin, thereby providing a display apparatus having a long-life and low-power consumption.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a perspective view showing a display apparatus according to an embodiment of the present disclosure.

FIG. 2 is a diagram showing a detailed structure of a mounting part according to an embodiment of the present disclosure.

FIG. 3 is a cross-sectional view taken along a cutting line 3-3 of the display apparatus according to an embodiment of the present disclosure of FIG. 1.

FIG. 4 is a side view showing a display apparatus according to another embodiment of the present disclosure.

FIG. 5 is a block diagram schematically showing an internal structure of a display apparatus according to an embodiment of the present disclosure.

FIG. 6A to FIG. 6D are diagrams showing various embodiments of a damping portion of a mounting part according to an embodiment of the present disclosure.

FIG. 7 is a diagram showing various shapes of each of metal particles or the acrylic material particles contained in a damping portion according to an embodiment of the present disclosure.

FIG. 8 is a graph showing a HIC value based on a content of a metal or acrylic material added to a damping portion according to an embodiment of the present disclosure.

FIGS. 9A to 9D are diagrams showing various embodiments of a damping portion of a mounting part according to some further embodiments of the present disclosure.

FIG. 10 is a diagram showing an example of absorbing a shock when the shock is applied to a display apparatus according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the claims are not limited by the disclosure.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure. The claims are not limited by the disclosure.

A shape, a size, a ratio, an angle, a number, etc., disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B through another node unless a phrase ‘immediately transferred’ or ‘directly transferred’ is used.

As used herein, the term “display apparatus” may refer to, in a narrow sense, a display apparatus such as a liquid crystal module (LCM), an organic light-emitting diode (OLED) module, or a quantum dot (QD) module including a display panel and a driver for driving the display panel. Moreover, the display apparatus may refer to, in a broad sense, a laptop computer, a television, a computer monitor, an automotive device or an equipment display for a vehicle, a set electronic device, a set device or a set apparatus which are a complete product or a final product including the LCM, the OLED module, or the QD module.

Therefore, the display apparatus in accordance with the present disclosure may include, in the narrow sense, a display apparatus itself including, for example, the LCM, the OLED module, QD module, etc., and may include, in a broad sense, the set device as an application product or an end-user device which are a complete product or a final product including the LCM, the OLED module, or the QD module.

Moreover, in some cases, the LCM, OLED module, or QD module composed of the display panel and the driver may be expressed as “display apparatus” in a narrow sense. The electronic device as a complete product including the LCM, OLED module or QD module may be expressed as “set” device” in a broad sense. For example, the display apparatus in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. The display panel used in the disclosure may be not limited to a specific display panel including a flexible substrate for the OLED display panel and an underlying back plate support structure and having a bendable bezel. Moreover, the display panel used in the display apparatus according to an embodiment of the present disclosure is not limited to a shape or a size of the display panel.

More specifically, when the display panel is embodied as the organic light emitting diode (OLED) display panel, the display panel may include a plurality of gate lines and data lines, and pixels respectively formed in areas where the gate lines and the data lines intersect with each other. Moreover, the display panel may be configured to include an array including a thin-film transistor as an element for selectively applying a voltage to each pixel, an organic light-emitting element layer on the array, and an encapsulation substrate or an encapsulation layer disposed on the array to cover the organic light-emitting element layer. The encapsulation layer protects the thin-film transistor and the organic light-emitting element layer from external impact, and may prevent moisture or oxygen from penetrating into the organic light-emitting element layer. Moreover, the light emitting layer formed on the array may include an inorganic light emitting layer, for example, a nano-sized material layer, or a quantum dot.

Hereinafter, according to an embodiment of the present disclosure, a display apparatus that a mounting part used for mounting and fixing the display apparatus onto a dashboard of a vehicle can satisfy the head impact criterion (HIC) will be described.

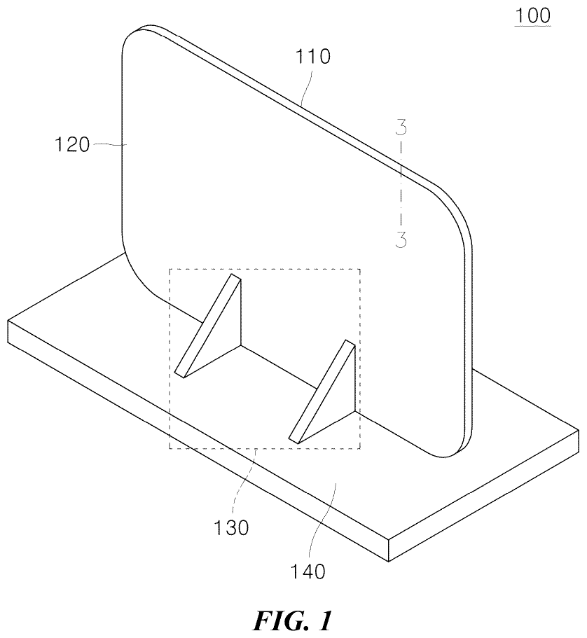

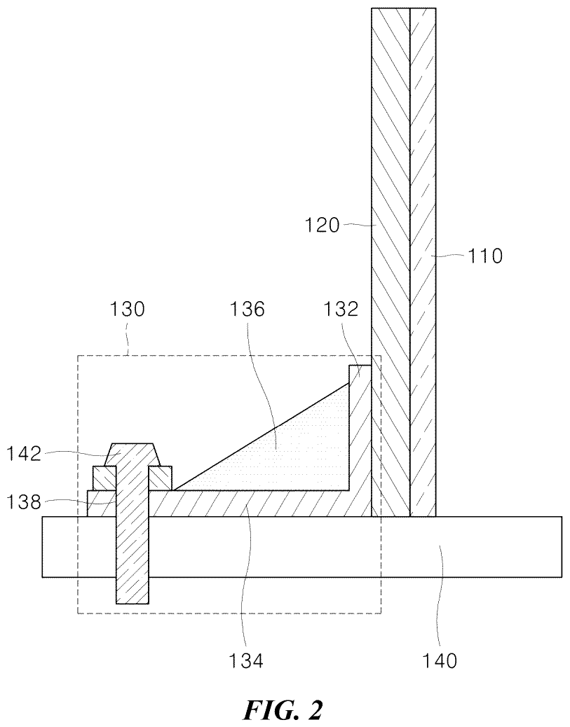

FIG. 1 is a perspective view showing a display apparatus according to an embodiment of the present disclosure, and FIG. 2 is a drawing showing a detailed structure of a mounting part according to an embodiment of the present disclosure.

Referring to FIG. 1, a display apparatus 100 according to an embodiment of the present disclosure may include a cover glass module 110, a back cover 120, and a mounting part 130.

The cover glass module 110 may include a display panel that displays an image.

The back cover 120 may be coupled to the cover glass module 110 to support the cover glass module 110. The back cover 120 may be made of a rubber material. The back cover 120 may be made of acrylic material. The back cover 120 may be made of a mixture of rubber and acrylic material.

The back cover 120 may be made of one of polymethylmethacrylate (PMMA), polycarbonate (PC), cycloolefin polymer (COP), polyethylene terephthalate (PET), polyimide (PI), and polyaramid (PA) having impact resistance. However, embodiments of the present disclosure are not limited thereto.

The mounting part 130 may fix the back cover 120 to a dashboard 140 of the vehicle. Referring to FIG. 2, the mounting part 130 may include a coupling portion 132 coupled to the back cover 120, a support portion 134 for supporting the coupling portion 132, and a damping portion 136 that absorbs an impact applied to the back cover 120. A bolt receiving hole 138 for receiving a bolt 142 therein is formed in the support portion 134. The bolt 142 may be inserted into the bolt receiving hole 138 of the support portion 134 such that the mounting part 130 may fix the back cover 120 to the dashboard 140.

The damping portion 136 may be made of a rubber material. However, embodiments of the present disclosure are not limited thereto.

The damping portion 136 may be made of a mixture of rubber and metal. However, embodiments of the present disclosure are not limited thereto.

The metal may include aluminum (Al) or iron steel. However, embodiments of the present disclosure are not limited thereto.

The aluminum (Al) or iron steel accounts for 10% to 30% of the content of the damping portion 136. A content of aluminum or iron steel may be in a range of 10% to 30% by weight based on a total weight of the damping portion 136. However, embodiments of the present disclosure are not limited thereto.

The damping portion 136 may be made of a mixture of rubber and acrylic material. However, embodiments of the present disclosure are not limited thereto.

The acrylic material accounts for 10% to 30% of the content of the damping portion 136. A content of acrylic material may be in a range of 10% to 30% by weight based on a total weight of the damping portion 136. However, embodiments of the present disclosure are not limited thereto.

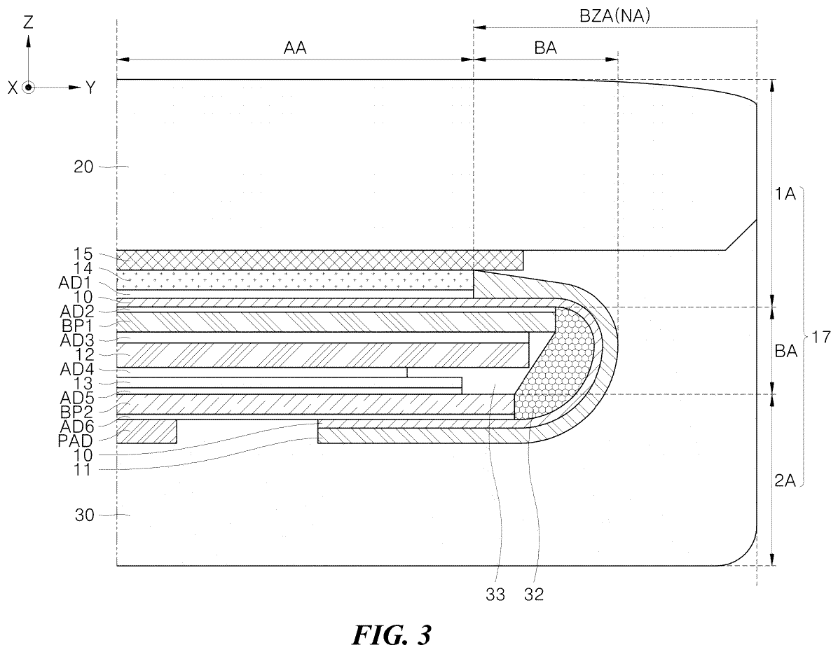

FIG. 3 is a cross-sectional view taken along a cutting line 3-3 of the display apparatus according to an embodiment of the present disclosure as shown in FIG. 1.

Referring to FIG. 3, the display apparatus 100 according to an embodiment of the present disclosure may include a display panel 10, a cover member 20, and a back frame 30.

The display apparatus 100 may include a display panel 10, a cover member 20 disposed on the display panel 10, and a back frame 30 disposed under the display panel 10 so as to support the cover member 20 and the display panel 10.

The display panel 10 may include a flexible board. However, embodiments of the present disclosure are not limited thereto. The display panel 10 may include a display area (Active Area) AA and a bezel area BZA in a front surface thereof, and the bezel area BZA may include a bent area BA. The bezel area BZA may extend along the outermost edge of the display apparatus 100 so as to surround the display area AA.

The display panel 10 may include a first area 1A as a front surface of the display panel 10, and a second area 2A as a back surface of the display panel. In this regard, the second area 2A may include the bent area BA. In the display panel 10. The first area 1A, the bent area BA, and the second area 2A may be arranged in a vertical direction. For example, the display panel 10 may have a flat shape in the first area 1A, and a bent shape in the bent area BA. One side thereof may be bent and the other side thereof may be flat in the second area 2A.

The bent area BA may be disposed between the first area 1A and the second area 2A in the vertical direction. The bent area BA may be disposed between the first area 1A and the second area 2A in the vertical direction so as to partially overlap the second area 2A.

The cover member 20 may include a cover window and a cover glass. The display module 17 may be disposed between a lower surface of the cover member 20 and an upper surface of the back frame 30.

The display module 17 may include a structure in which an optical adhesive layer 15 is disposed on top of the display panel 10 and a reinforcement member 11 is disposed under the display panel 10. However, embodiments of the present disclosure are not limited thereto. For example, the display module 17 may include a structure from the back frame 30 located under the display panel 10 to the cover member 20 located on top of the display panel 10.

The cover member 20 may be disposed to constitute a front surface of the display module 17 and may serve to protect the display module 17 from external shock. The cover member 20 transmits light emitted from the display panel 10 therethrough so that the image displayed on the display panel 10 is visible to a viewer in front of the display apparatus. This cover member 20 may be made of one of polymethylmethacrylate (PMMA), polycarbonate (PC), cycloolefin polymer (COP), polyethylene terephthalate (PET), polyimide (PI), and polyaramid (PA) having impact resistance and light transparency. However, embodiments of the present disclosure are not limited thereto.

An edge portion of the cover member 20 may have a rounded shape that is curved toward the back surface or lower surface of the display module 17.

In this case, the cover member 20 may be disposed to cover at least a partial area of a side surface of a low level of the display module 17, thereby protecting not only the front surface of the display module 17 but also the side surface thereof from external impact.

Since the cover member 20 may include the display area AA that displays the screen, the cover member may be made of a transparent material such as cover glass to display a screen therethrough. For example, the cover member 20 may be made of transparent plastic, glass, or reinforced glass. However, embodiments of the present disclosure are not limited thereto.

The back frame 30 may be disposed on the back surface or low surface of the display module 17 to accommodate the display module 17 therein and may be in contact with the cover member 20 to support the cover member 20.

The back frame 30 may serve as a housing that constituting an outer back surface of the display apparatus 100 and may be made of a metal material or an epoxy-based resin material. However, embodiments of the present disclosure are not limited thereto.

In this case, the back frame 30 may function as a casing constituting an outer appearance of the display apparatus 100. However, embodiments of the present disclosure are not limited thereto. For example, the back frame 30 may function as a middle frame that serves as a housing that protects the rear surface of the display module 17.

As shown in FIG. 3, a front surface of the cover member 20 may be divided into the display area AA and the non-display area NA as an area other than the display area AA. The non-display area NA may be formed along an edge of the display area AA in the front surface of the cover member 20. The non-display area NA may include a bezel area BZA.

The display module 17 may be coupled to a back surface (or a lower surface) of the cover member 20.

The display module 17 coupled to the back surface (or the lower surface) of the cover member 20 may have the bent area BA. The bent area BA may be located under the cover member 20 in the −Z axis direction in the bezel area BZA.

To reduce the bezel area BZA, it is necessary to reduce a radius of curvature of the bent area BA.

The radius of curvature of the bent area BA is proportional to a total thickness of the display module 17 and, thus, the display apparatus 100. Thus, when the total thickness increases, the radius of curvature of the bent area BA increases. When the total thickness decreases, the radius of curvature of the bent area BA decreases.

Therefore, in order to prevent the size of the bezel area BZA from increasing, it is necessary to prevent the total thickness of the display module 17 and thus, the display apparatus 100 from increasing.

In FIG. 3, the first area 1A may have a vertical structure from the display panel 10 that displays the image to the cover member 20 in an upward direction, and thus may be a display area in the vertical direction.

The second area 2A may be located under the first area 1A and may include the back frame 30 on which the image is not displayed. The bent area may be disposed between the first and second areas in the vertical direction.

In the first area 1A, the display module 17 may have an optical control layer 14 disposed on top of the display panel 10 and bonded thereto through a first adhesive layer AD1, and the cover member 20 disposed on top of the optical control layer 14 and bonded thereto through an optical adhesive layer 15.

The optical control layer 14 may include, for example, a polarizing layer POL. The optical control layer 14 prevents the contrast ratio CR from decreasing due to external light. In the display apparatus 100 according to the present disclosure, the display panel may be embodied as an OLED panel. In this case, when the display panel operates in an operation mode that displays an image, the optical control layer 14 that blocks external light incident from the outside may be placed into a travel path of the light emitted through the display panel such that the contrast ratio is improved. The optical control layer 14 is not an essential component in an embodiment of the present disclosure and may not be included. However, embodiments of the present disclosure are not limited thereto.

The optical adhesive layer 15 may include a transparent optical adhesive OCA (Optical Clear Adhesive). The optical adhesive layer 15 may have a thickness of, for example, 100 to 300 μm. When the thickness of the optical adhesive layer 15 is smaller than 100 μm, the adhesive strength becomes weak, making it difficult to modularize the cover member 20 and first and second support members BP1 and BP2. When the optical adhesive layer 15 has a thickness exceeding 300 μm, the display apparatus 100 may not be bent. Accordingly, the optical adhesive layer 15 may have a thickness in a range of 100 to 300 μm.

Although not shown in FIG. 3, a black matrix may be disposed on the back surface (or the lower surface) of the cover member 20. The black matrix may be disposed in the non-display area NA or the bezel area BZA through which light does not transmit, and serves to prevent light leakage.

In the bent area BA, the display module 17 may have the first support member (Back Plate 1) BP1 disposed under the display panel 10 and adhered thereto through a second adhesive layer AD2, and a plate 12 disposed under the first support member BP1 and adhered thereto through the third adhesive layer AD3. The first support member BP1 may be disposed under the display panel 10 to supplement the rigidity of the display panel 10 and may maintain the display panel 10 disposed in the first area 1A in a flat state.

A connection member (Bezel Bending Fixing Tape) 13 may be disposed under the plate 12 and adhered thereto through a fourth adhesive layer AD4, and the second support member BP2 may be disposed under the connection member 13 and adhered thereto through a fifth adhesive layer AD5.

The plate 12 may support the display panel 10 and the first support member BP1, and thus may be referred to as a support member. The plate 12 may include a heat dissipation sheet, and may include a metal layer that may reflect external light therefrom. However, embodiments of the present disclosure are not limited thereto. The fifth adhesive layer AD5 may include a double-sided tape, a double-sided foam adhesive tape, or a double-sided foam adhesive pad. Although not shown in the drawing, the plate 12 may include an embossed layer in contact with the first support member BP1; a cushion layer disposed under the embossed layer and having a shock-relieving function; and a heat dissipation layer disposed under the cushion layer and having a heat dissipation function.

The connection member 13 may fix a bent state of the bezel. The connection member 13 may be located between the second support member BP2 and the plate 12 and may fix a bent state of the display panel 10 between the first area 1A and the second area 2A.

In the display apparatus 100, the second support member BP2 may be disposed in the second area 2A of the display module 17. The second support member BP2 may be disposed on top of the bent portion of the display panel 10. The second support member BP2 may support the display panel 10 in the second area 2A. To this end, a lower surface of the second support member BP2 may face an upper surface of the bent portion of the display panel 10 and may be adhered to the upper surface of the bent portion of the display panel 10 through a sixth adhesive layer AD6.

The second support member BP2 may be spaced apart from the first support member BP1 by a certain distance in the vertical direction. In an area where the first support member BP1 and the second support member BP2 are spaced from each other, a lower surface of the first support member BP1 and an upper surface of the second support member BP2 may face each other.

The support member BP1, BP2, and 12 may support the display panel 10. The support member BP1, BP2, and 12 may include the first support member BP1, the second support member BP2, and the plate 12. The first support member BP1 may support a portion of the display panel 10 in the first area 1A and the bent area BA. The second support member BP2 may support a portion of the display panel 10 in the second area A2. The plate 12 may be disposed between the first support member BP1 and the second support member BP2 to support a flat surface of the display panel 10.

When a single support member extending in the first area 1A, the bent area BA, and the second area 2A is cut and removed in the bent area BA, the first support member BP1 may be located on top of the plate 12 and under the display panel 10 in the first area 1A, while the second support member BP2 may be located under the plate 12 in the second area 2A including the bent portion of the display panel 10. In this regard, when the support member is cut and removed in the bent area BA, the display panel 10 is exposed in the bent area BA, and then the reinforcement member 11 and the display panel 10 in the bent area BA are bent and then the connection member 13 is bonded to the second support member BP2 through the fifth adhesive layer AD5.

The first support member BP1 and the second support member BP2 may have the same height. Alternatively, the first support member BP1 and the second support member BP2 may have different heights. In the present disclosure, the heights of the first support member BP1 and the second support member BP2 are not limited thereto.

Each of the first support member BP1 and the second support member BP2 may have a strength and a thickness equal to or greater than a certain value to supplement the rigidity of the display panel 10. Since the first support member BP1 is formed to have the strength and thickness equal to or greater than the certain value to supplement the rigidity of the display panel 10, the first support member BP1 may be not formed on the bent portion of the display panel 10 in the bent area BA and the second area 2A. However, embodiments of the present disclosure are not limited thereto.

Based on a shape of the display panel 100 before being bent, the second support member BP2 may be disposed under the display panel 100 so as to be spaced apart from the first support member BP1 horizontally. The second support member BP2 may be disposed under the display panel 100 and may supplement the rigidity of the display panel 100 and maintain the display panel 100 in a flat state. Since the second support member BP2 is formed to have the strength and thickness equal to or greater than the certain value to supplement the rigidity of the display panel 100, the second support member BP2 may not be formed on a portion of the display panel 100 corresponding to a portion of the bent area BA. However, embodiments of the present disclosure are not limited thereto.

After the display panel 100 has been bent, the second support member BP2 may be disposed on top of the display panel 100 in the bent area BA and the second area 2A.

The plate 12 having a flat shape may be disposed between the first support member BP1 and the second support member BP2.

The plate 12 may support the flat surface of the display panel 10 while being disposed between the first support member BP1 and the second support member BP2. The plate 12 may include, for example, a metal to reinforce a supporting force of the first support member BP1 and the second support member BP2. Furthermore, the plate 12 may include one or a combination of stainless steel (SUS), glass, ceramic, and metal. Furthermore, the plate 12 may be made of a plastic material including at least one of polycarbonate (PC), polyimide (PI), polyethylene naphthalate (PEN), and polyethylene terephthalate (PET). However, embodiments of the present disclosure are not limited thereto.

In the display module 17, in the second area 2A, the bent portion of the display panel 10 and a pad PAD may be disposed under the second support member BP2. The pad PAD may be bonded to the second support member BP2 through the sixth adhesive layer AD6.

When the display panel 10 has been bent in the bent area BA in a state in which the pad PAD is disposed under the display panel 10, the display panel 10 may receive a strong restoring force for restoring the same to its state before the bending. When the strong restoring force acts on the display panel 10, the pad PAD may not be fixed and may lift off.

To solve this problem, the connection member 13 may be disposed between the back surface (or the lower surface) of the display panel 10 and the pad PAD and serves to fix the bent portion of the display panel 10 so that the display panel may maintain its bent shape. The connection member 13 may be formed to have a constant thickness and may be embodied as a double-sided tape with a strong adhesive force that may secure the pad PAD and the front portion of the display panel 100 to each other. The connection member 13 may include at least one layer and may be made of at least one of OCA (Optical Clear Adhesive), OCR (Optical Clear Resin), or a pressure sensitive adhesive (PSA). The connection member 13 may be present in a form of a foam tape or a foam pad with a shock absorbing function or a double-sided tape with conductivity. For example, the double-sided conductive tape may include an upper adhesive layer, a lower adhesive layer and a conductive layer between the upper adhesive layer and the lower adhesive layer, wherein each of the upper adhesive layer and the lower adhesive layer may include a conductive material.

A bent reinforcement member 11 may be disposed under the bent portion of the display panel 10. The bent reinforcement member 11 may include, for example, a micro coating layer. The micro coating layer MCL may be referred to as a micro cover layer MCL. The bent reinforcement member 11 may be disposed on an outer surface of the display panel 10 in the bent area BA.

The reinforcement member 11 may extend so as to cover the display panel 10 in the bent area BA, may cover a portion of the display panel 10 in the first area 1A in contact with the bent area BA, and may cover the bent portion of the display panel 10 in the second area 2A.

The reinforcement member 11 improves the deformation of the display panel 100 in the bent area BA and allows the display panel 100 to be bent at a constant curvature. The reinforcement member 11 may be composed of a resin layer to compensate for the weakening of the rigidity due to the bending of the display panel 100 in the bent area BA. Furthermore, the reinforcement member 11 may be made of a polymer such as polyimide (PI) or polyethylene terephthalate (PET). When the reinforcement member 11 is embodied as a polymer film, the reinforcement member 11 may have a modulus of about 1 to about 10 GPa. However, embodiments of the present disclosure are not limited thereto.

The reinforcement member 11 may include resin, for example, ultraviolet (UV) curable acrylic resin. Embodiments of the present disclosure are not limited thereto. Specifically, the reinforcement member 11 may be made of a cured product of resin obtained by coating the resin and performing a curing process on the coated resin. When the resin is the ultraviolet curable resin, the resin may be cured using ultraviolet rays.

The reinforcement member 11 may be disposed on the outer surface of the display panel 100 to cover various signal lines between an encapsulation portion and the pad of the display panel 100. Therefore, the reinforcement member 11 may prevent moisture penetration into the signal line while protecting the signal line from external shock.

Furthermore, the reinforcement member 11 may be disposed on the outer surface of the display panel 100 in the bent area BA and thus may supplement the rigidity of the display panel 100 in the bent area BA where a support member is absent. The support member may be adhered to a lower surface of the display panel 100 such that the support member is absent in an area corresponding to the bent area BA. Thus, when the display panel has been bent, the first support member BP1 may remain on the lower surface of the display panel 100 in the first area 1A, and the second support member BP2 may remain on a top surface of the bent portion of the display panel 100 in the second area 2A. Therefore, the rigidity of the display panel 100 in the bent area BA in which the support member is absent may be weakened. Thus, the rigidity thereof in the bent area BA may be supplemented by the reinforcement member 11 attached to the outer surface of the display panel 100 in the bent area BA.

The back frame 30 may be disposed under the reinforcement member 11, under the cover member 20, and under the bent portion of the display panel 10.

The back frame 30 may support the bezel area BZA of the cover member 20 and may support the first area 1A, the second area 2A, and the bent area BA of the display panel 10. For this purpose, the back frame 30 may be in contact with the cover member 20 in the first area 1A, and may be in contact with a side surface of the reinforcement member 11 in the bent area BA and may be in a contact with a bottom of the reinforcement member 11 in the second area 2A, and may contact the bent portion of the display panel 100 in the second area 2A.

The back frame 30 may include an epoxy resin. The epoxy resin may include an epoxy-based resin.

The back frame 30 may have a flat portion and a vertical portion protruding perpendicularly and upwardly from an edge of the flat portion. The flat portion of the back frame 30 may be attached to a rear surface of the reinforcement member 110 by way of adhesive means of a resin or a tape. Embodiments of the present disclosure are not limited thereto. A top of a vertical portion of the back frame 30 may be adhered to the cover member 20 using, for example, a double-sided tape.

The back frame 30 has a box shape with an open top, and may accommodate the display module 17 therein. The back frame 30 may include a metal. In this case, the back frame 30 made of the metal may accommodate therein the component including the display panel 10 disposed on the back surface (or the lower surface) of the cover member 20, and may protect the components.

Alternatively, the back frame 30 may be made of a plastic material such as resin with a shock-absorbing function. In this case, an impact due to an external force above a certain pressure is applied to the back frame 30, the shock may be alleviated by the shock-absorbing function of the plastic material. Therefore, the cushioning effect of the back frame 30 may prevent cracks from occurring in the display panel 10 and may protect the display panel 10.

When the back frame 30 according to an embodiment of the present disclosure is made of the epoxy resin, the back frame may be thinner and may effectively protect the bent area BA, thereby enabling a narrow bezel of the display apparatus 100.

When the back frame 30 according to an embodiment of the present disclosure is made of the epoxy resin, an air gap may be absent in the display module including the display panel 100 of the display apparatus 100 such that micro movement of the display module may not occur. Thus, the back frame 30 may fix the display module in a more durable manner. Further, referring to FIG. 3, in the display apparatus 100 according to an embodiment of the present disclosure, the bent area BA may include a third area (Potting Area) 32 and a fourth area (No Vacant Area) 33 defined inwardly of the bent portion of the display panel 10.

The third area (Potting Area) 32 defined inwardly of the bent portion of the display panel 10 may be filled with a resin (potting resin) including an organic insulating material.

In this regard, the resin may include an organic insulating material including, for example, polyacrylate and polyimide.

The fourth area 33 may refer to an area defined inwardly of the bent portion of the display panel 10 other than the third area (Potting Area) 32 filled with a resin (potting resin).

Accordingly, the bent area BA of the display panel 10 formed after the display panel 10 has been bent may include the third area 32 and the fourth area 33. In this regard, in the bent area BA of the display panel 10 formed after the display panel 10 has been bent, the resin filling the third area 32 may flow into the fourth area 33 to fill the fourth area 33 so that there is no air gap.

A process of filling the third area 32 with the resin is not shown in the drawing. However, in this process, a first dam and a second dam are disposed at both opposing ends of the third area 32 in the bent area BA, respectively, and the resin may fill an area between the first dam and the second dam defined inwardly of the bent portion of the display panel 10 in the bent area BA.

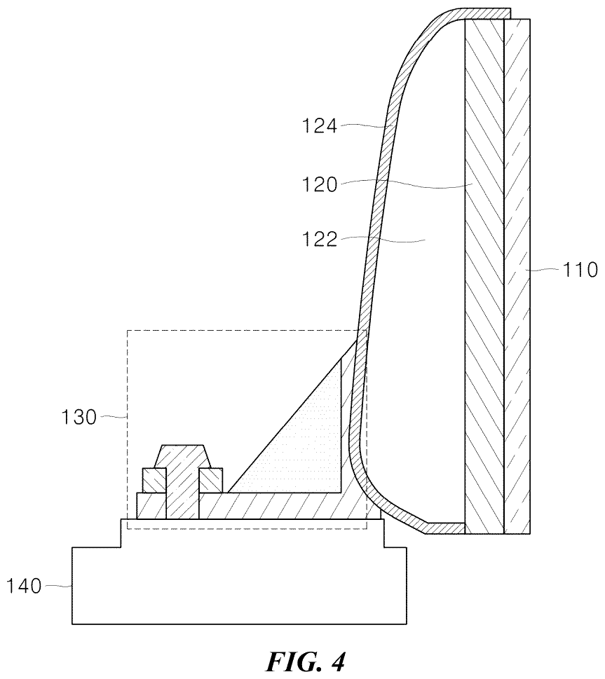

FIG. 4 is a side view showing a display apparatus according to another embodiment of the present disclosure.

Referring to FIG. 4, in the display apparatus according to another embodiment of the present disclosure, unlike the back cover 120 of FIG. 2 as described above, the back cover 120 coupled to the mounting part 130 through a connection portion 124 having a shock-absorbing space 122 defined therein.

In this regard, the connection portion 124 may be made of the same material as that of the back cover 120. The connection portion 124 and the back cover 120 may be formed to be integral with each other into a single body in an injection molding manner such that the shock-absorbing space 122 is defined therebetween.

The shock-absorbing space 122 defined between the back cover 120 and the connection portion 124 may serve to absorb the impact force applied to the back cover 120 when the driver or passenger's head hits the cover glass module 110 or the back cover 120 when the vehicle collision occurs.

This configuration may minimize or prevent the head injury to the driver or the passenger riding in the vehicle.

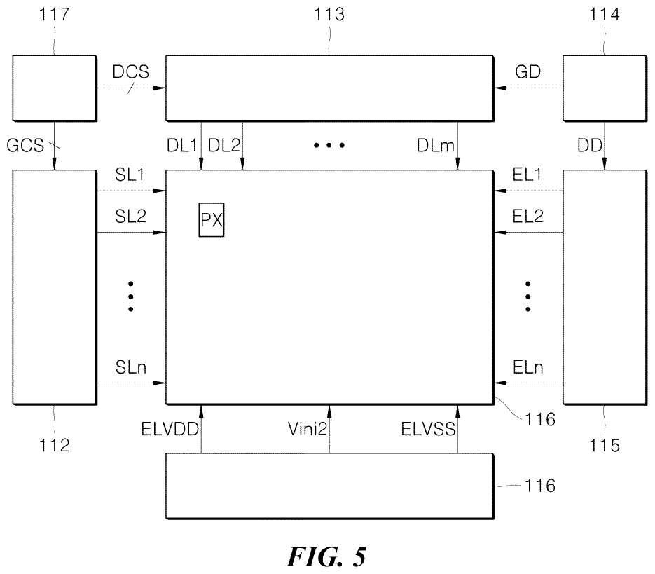

FIG. 5 is a block diagram schematically showing an internal structure of the display apparatus according to an embodiment of the present disclosure.

Referring to FIG. 5, the display apparatus 100 according to an embodiment of the present disclosure may include a luminance controller 114, the display panel 10 in which a number of pixels are defined, a scan driver 112, a data driver 113, a light-emission controller 115, a power supply 116 connected to the display panel 10, and a timing controller 117.

The luminance controller 114 provides one gamma set selected from among a plurality of gamma sets, each including a plurality of gamma data, to the data driver 113, and provides dimming data DD corresponding to the selected gamma set to the light-emission controller 115.

The display panel 10 may include a plurality of pixels PX. In this connection, each of the pixels PX may have an organic light-emitting diode.

In the display panel 10, a plurality of gate lines GL and a plurality of data lines DL intersect each other, and each pixel PX is defined at each intersection therebetween.

That is, in the display panel 10, the plurality of gate lines GL and the plurality of data lines DL are formed on an organic substrate or a plastic substrate and intersect with each other. Each of pixels PX corresponding to red R, green G, and blue B colors is defined at each of intersections between the gate lines GL and the data lines DL.

The scan and data lines SL and DL of the display panel 10 may be respectively connected to the scan driver 112 and the data driver 113 formed outside of the display panel 10. Further, in the display panel 10, power voltage supply lines ELVDD, Vini2, and ELVSS extending in a direction parallel to the data line DL are connected to each pixel PX.

Further, although not shown, each pixel PX includes at least one organic electroluminescent diode, a capacitor, a switching thin-film transistor, and a driving thin-film transistor. In this connection, the organic electroluminescent diode may be composed of a first electrode (hole injection electrode), an organic compound layer, and a second electrode (electron injection electrode).

The organic compound layer may further include various organic layers for efficiently transmitting hole or electron carriers to the light-emitting layer, in addition to the light-emitting layer that emits light. The various organic layers may include a hole injection layer and a hole transport layer positioned between the first electrode and the light-emitting layer, and an electron injection layer and an electron transport layer positioned between the second electrode and the light-emitting layer.

Further, the switching and driving thin-film transistors are connected to the scan line SL and a control signal supply line CL and the data line DL. The switching thin-film transistors are turned on according to a gate voltage input to the scan line SL. At the same time, a data voltage input to the data line DL is transmitted to the driving thin-film transistor. The capacitor is connected and disposed between the thin-film transistor and the power supply line, and is charged with the data voltage transmitted from the thin-film transistor and is maintained for one frame.

Moreover, the driving thin-film transistor is connected to the power supply line and the capacitor, and provides a drain current corresponding to a voltage across a gate and the source to the organic electroluminescent diode. Accordingly, the organic electroluminescent diode emits light using the drain current. In this connection, the driving thin-film transistor includes a gate electrode, source electrode and a drain electrode. An anode of the organic electroluminescent diode is connected to one electrode of the driving thin-film transistor.

The scan driver 112 applies a scan signal to the plurality of scan lines SL. That is, the scan driver 112 sequentially applies a gate voltage to each pixel PX on a single horizontal line basis, in response to the gate control signal GCS. The scan driver 112 may be implemented as a shift register having a plurality of stages sequentially outputting a high-level gate voltage every one horizontal period.

The data driver 113 applies a data signal to the plurality of data lines DL. That is, the data driver 113 receives an image signal in a digital waveform applied from the timing controller 117 and converts the image signal into an analog data voltage having a gray level value that may be processed by the pixel PX. Further, in response to the data control signal DCS input thereto, the data driver 113 supplies the data voltage to each pixel PX through the data line DL.

In this connection, the data driver 113 converts the image signal into the data voltage using a number of reference voltages supplied from a reference voltage supply (not shown).

As described above, the luminance controller 114 provides one gamma set selected from among a plurality of gamma sets, each including a plurality of gamma data, to the data driver 113, and apply the dimming data DD corresponding to the selected gamma set to the light-emission controller 115.

The light emission controller 115 applies a light-emission control signal EL1 to ELn corresponding to the dimming data DD to the plurality of pixels.

The power supply 116 provides a high power voltage ELVDD, a low power voltage ELVSS and an initialization voltage Vini2 to each pixel.

The timing controller 117 controls the scan driver 112 and the data driver 113. That is, the timing controller 117 receives the image signal, and timing signals such as a clock signal, and vertical and horizontal synchronization signals as externally applied, and generates the gate control signal GCS and a data control signal DCS.

In this connection, the horizontal synchronization signal represents a time duration required to display one line of a screen. The vertical synchronization signal represents a time duration required to display a screen of one frame. Further, the clock signal refers to a reference for generating control signals for the gate and the drivers.

In one example, although not shown, the timing controller 117 is connected to an external system through a predefined interface and receives the image-related signals and the timing signals output therefrom at high speed without noise. The interface may employ an LVDS (Low Voltage Differential Signal) scheme or a TTL (Transistor-Transistor Logic) interface scheme.

Further, the timing controller 117 according to an embodiment of the present disclosure may incorporate therein a microchip (not shown) equipped with a compensation model that generates a compensation value for the data voltage according to a current deviation of each pixel. Thus, the voltage compensation value may be applied to the image signal to be provided to the data driver 113 so that the data voltage to be supplied from the data driver 113 is subjected to compensation based on the voltage compensation value.

In this connection, the microchip (not shown) may have a compensation model created by learning, for example, a temperature, a weighted time, average brightness, applied data signal, and an initial data signal for each pixel using a deep learning scheme. In this connection, the data signal means the data voltage. Moreover, the compensation model may be created by a computer simulator that learns the temperature, the weighted time, the average brightness, the applied data signal, and the initial data signal for each pixel using the deep learning scheme.

Therefore, the microchip may input the data signal to the compensation model and thus generate a compensated data signal. The timing controller 117 applies the generated compensated data signal to the data driver 113.

In one example, a driving integrated circuit may be disposed on the other surface of the pad of the display panel 10, while the second support member BP2 is disposed on one surface of the pad of the display panel.

The driving integrated circuit may be mounted on the display panel 10 in a chip bonding process or a surface mounting process. Based on the bent state, the driving integrated circuit may be disposed under the display panel 10. For example, the driving integrated circuit may be disposed on a bottom of the pad.

In this case, a flexible printed circuit board (not shown) may be disposed between the pad and the driving integrated circuit such that the driving integrated circuit may be located on the back surface (or the lower surface) of the flexible printed circuit board (FPCB).

The driving integrated circuit generates a data signal and a gate control signal based on the image data and timing synchronization signals supplied from an external host driving system. Then, the driving integrated circuit supplies the data signal to the data line of each pixel through the pad and may supply the gate control signal to the gate driving circuit (not shown) through the pad.

The driving integrated circuit may be mounted in a chip mounting area defined in the display panel 10 and may be electrically connected to the pad, and may be connected to a signal line connected to each of the gate driver and a pixel array disposed in the display panel 10.

Since the driving integrated circuit generates considerable heat, it is necessary to effectively dissipate the heat from the driving integrated circuit. The heat from the driving integrated circuit may be mainly dissipated by the support member.

The pad PAD may be disposed on one side of the display panel 10 on which the driving integrated circuit is mounted.

The pad PAD on the rear surface of the display panel 10 may be electrically connected to the flexible printed circuit board on which the circuit board is mounted.

One side of the flexible printed circuit board may be electrically connected to the pad provided on one side of the display panel 10 in a film attachment process using a conductive adhesive layer. The flexible printed circuit board may be located on the back surface (or the lower surface) of the display panel 10.

In this case, the conductive adhesive layer may include an anisotropic conductive film (ACF) by way of example.

The circuit board may provide the image data and the timing synchronization signals supplied from the host driving system to the driving integrated circuit, and may provide a voltage required to drive each of the pixel array, the gate driver, and the driving integrated circuit thereto.

The flexible printed circuit board having one side connected to the display panel 10 may be formed to extend along together with the display panel 10 such that the flexible printed circuit board may be bent toward a back surface (or a lower surface) of a front portion of the display panel 10.

The flexible printed circuit board having one side connected to the display panel 10 may extend from one side thereof so as to be located on the back surface (or the lower surface) of the display panel 10 that is not covered with the pad PAD of the display panel 10.

Therefore, at least a portion of the flexible printed circuit board may contact the back surface (or the lower surface) of the display panel 10.

The display apparatus 100 according to an embodiment of the present disclosure refers to a display apparatus having flexibility, and may include a bendable display apparatus, a rollable display apparatus that may be rolled, an unbreakable display apparatus that does not break, and a foldable display apparatus that can be folded.

The driver integrated circuit may be implemented as a TFT (thin film transistor) in the non-display area NA. This driver integrated circuit may be referred to as a GIP (gate-in-panel) circuit. The GIP circuit includes a gate driver of a GIP structure, wherein the gate driver is embodied as a bottom gate type thin-film transistor (BG-T), and a source and drain metal film of a bridge line extends so as to connected to a drain electrode of the BG thin-film transistor.

Moreover, some components, such as the data driver IC may be mounted on a separate printed circuit board, or may be coupled to a connection interface (pads/bumps, pins, etc.) disposed in the non-display area NA using a circuit film such as FPCB (flexible printed circuit board), COF (chip-on-film), or TCP (tape-carrier-package). The non-display area NA may be bent along with the connection interface, so that the printed circuit (COF, PCB, etc.) may be disposed on the rear surface (or the back surface) of the display apparatus 100.

The display apparatus 100 according to the present disclosure may include various additional components for generating various signals or driving the pixel PX in the display area. The additional components to drive the pixel may include an inverter circuit, a multiplexer, an electrostatic discharge circuit. The display apparatus 100 according to the present disclosure may include additional components related to functions other than the function of driving the pixel. For example, the display apparatus 100 according to the present disclosure may include additional components that provide a touch sensing function, a user authentication function such as fingerprint recognition, a multi-level pressure sensing function, and a tactile feedback function. The above-mentioned additional components may be disposed in an external circuit connected to the non-display area NA and/or the connection interface.

According to the present disclosure, several portions of the display apparatus 100 may be bent along a bending line. The bending line may extend transversely, longitudinally, or diagonally. Accordingly, the display apparatus 100 according to an embodiment of the present disclosure may be bent in a combination of the transverse, longitudinal and diagonal directions based on a required design.

According to the present disclosure, one or more corner edges of the display apparatus 100 may be bent along the bending line so as to be away from a central portion. The bending line may be disposed closer to the edge of the display apparatus 100, but may extend across the central portion, or may extend diagonally from one or more corners of the display apparatus 100. This structure may enable the display apparatus 100 to be embodied as a foldable display apparatus or a display apparatus in which an image is displayed from each of both folded surfaces facing each other.

Since one or more portions of the display apparatus 100 may be bent, the display apparatus 100 according to the present disclosure may be divided into a substantially flat area and a curved area. One portion of the display apparatus 100 may be referred to as a substantially flat area. One portion of the display apparatus 100 may be bent at a predetermined angle, and this portion may be referred to as a bent area or a curvature area. The curvature area includes a bent section that is actually bent at a predetermined curvature radius.

The term “substantially flat” means that the substantially flat area includes a portion which is not perfectly flat. For example, a concave central portion and a convex central portion may belong to the substantially flat area in some embodiments. One or more bent sections may be present next to the concave central portion or the convex central portion, and are bent inwardly or outwardly at an angle relative to a bending axis along the bending line. The curvature radius of the curvature area is smaller than that of the flat area. In other words, the term “substantially flat area” means a portion with a smaller curvature than that of a portion adjacent thereto.

Depending on a position of the bending line, a portion on one side of the bending line is positioned toward the center of the display apparatus 100, while a portion on the other side of the bending line is positioned toward the edge of the display apparatus 100. A portion positioned toward the center of the display apparatus 100 may be referred to as a central portion, and a portion positioned toward the edge of the display apparatus 100 may be referred to as an edge portion. The central portion of the display apparatus 100 may be substantially flat, and the edge portion may be a bent section. However, this is not always true. The substantially flat area may also be disposed in the edge portion. Further, in some shapes of the display apparatus 100, the bent section may be disposed between two substantially flat areas.

When the non-display area NA is bent, the non-display area NA may be invisible or minimally visible to a viewer in front of the display apparatus 100. A portion of the non-display area NA visible to the viewer in front of the display apparatus 100 may be screened with a bezel. The bezel may be formed as a stand-alone structure, or as a housing or another suitable element. A portion of the non-display area NA visible to the viewer in front of the display apparatus 100 may be hidden under an opaque mask layer such as a black ink layer made of black ink (e.g., a polymer filled with carbon black). Such an opaque mask layer may be disposed on various layers (e.g., a touch sensor layer, a polarization layer, a cover layer, and the like) included in the display apparatus 100.

In some embodiments, the bent section of the display apparatus 100 may include a display area capable of displaying an image. That is, the bending line may be disposed in the display area so that at least some of pixels of the display area are included in the bent section.

The display apparatus 100 according to an embodiment of the present disclosure to which the structure of FIG. 5 as described above is applied may include the cover glass module 110 including the display panel 10; the scan driver 112 that supplies the scan signal to the display panel; the data driver 113 that supplies the data voltage to the display panel; the timing controller 117 that controls the scan driver and the data driver; the power supply 116 that provides the high power voltage ELVDD, the low power voltage ELVSS, and the initialization voltage Vini2 to the display panel; the back cover 120 coupled to the cover glass module and supporting the cover glass module; and the mounting part 130 for fixing the back cover to the dashboard of the vehicle.

In this regard, the mounting part 130 may include the damping portion 136 made of a mixture of rubber and metal or a mixture of rubber and acrylic material.

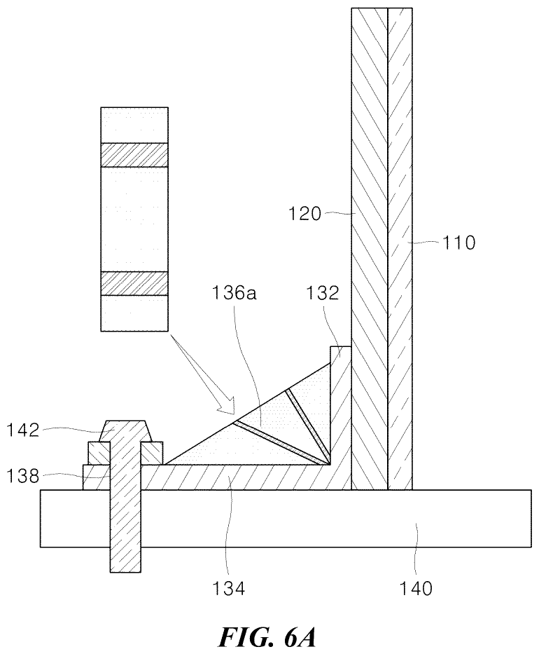

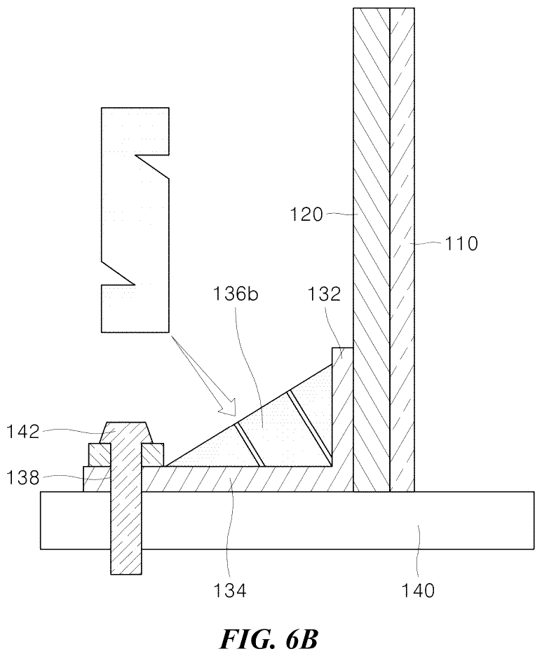

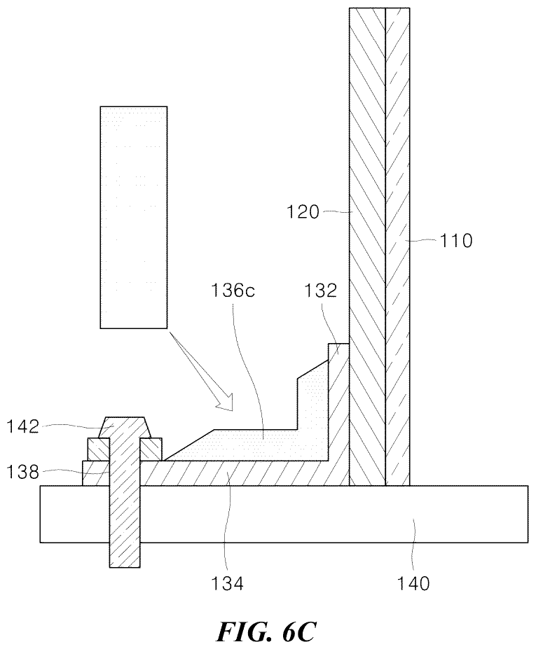

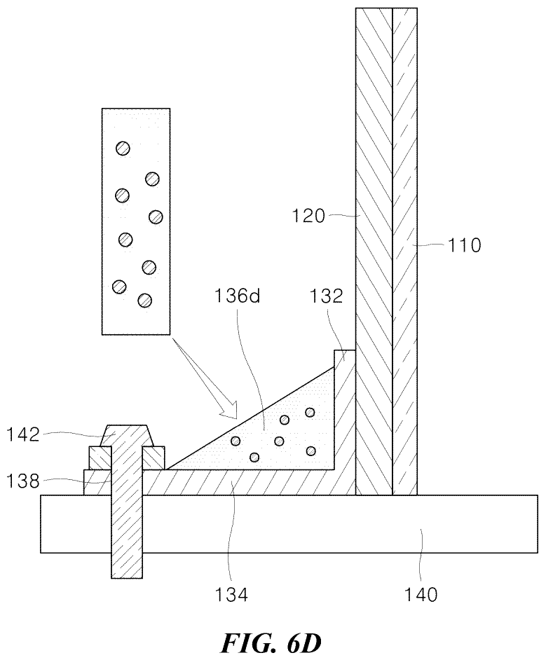

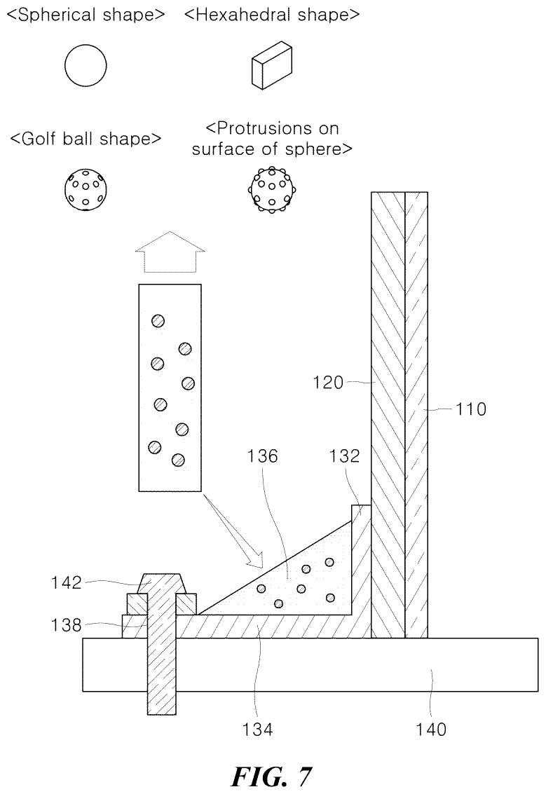

The damping portion 136 may be implemented based on combinations of various components as shown in FIGS. 6A to 6D and FIGS. 7A to 7D.

FIG. 6A to FIG. 6D are diagrams showing various embodiments of the damping portion of the mounting part according to an embodiment of the present disclosure.

Referring to FIG. 6A, a first damping portion 136a of the mounting part 130 according to an embodiment of the present disclosure may be formed to have two through-holes defined therein. The same material as that of the back cover 120 may fill the two through-holes.

The first damping portion 136a may include a polymer such as polyimide (PI) or polyethylene terephthalate (PET). The first damping portion 136a may include polymer epoxy resin. However, embodiments of the present disclosure are not limited thereto.

The first damping portion 136a may be made of one of polymethylmethacrylate (PMMA), polycarbonate (PC), cycloolefin polymer (COP), polyethylene terephthalate (PET), polyimide (PI), and polyaramid (PA) having impact resistance. However, embodiments of the present disclosure are not limited thereto.

Referring to FIG. 6B, a second damping portion 136b of the mounting part 130 according to an embodiment of the present disclosure may be made of a rubber material and may have two grooves defined therein.

The second damping portion 136b may reinforce its damping role using the two grooves (empty spaces).

Referring to FIG. 6C, a third damping portion 136c of the mounting part 130 according to an embodiment of the present disclosure may be made of a flexible material such as rubber, may have a flat bar or rectangular shape. The third damping portion 136c may be composed of a horizontal portion and a vertical portion defining 90 degrees therebetween. The horizontal portion and the vertical portion may be disposed on and correspond to the coupling portion 132 and the support portion 134 defining 90 degrees therebetween of the mounting part 130, respectively.

The third damping portion 136c has a right-angled shape along a right-angled shape of the combination of the coupling portion 132 and the support portion 134 of the mounting part 130. Thus, when an impact is applied to the back cover 120, the vertical and horizontal portions of the damping portion 136c may be folded relative to each other such that the impact force may be absorbed by the third damping portion 136c.

Referring to FIG. 6D, a fourth damping portion 136d of the mounting part 130 according to an embodiment of the present disclosure may be made of a flexible material such as rubber, and may contain a plurality of metal particles or acrylic material particles therein.

In this regard, each of the metal particles or the acrylic material particles may have one of following shapes: a spherical shape, a hexahedral shape, a golf ball shape, or protrusions on a surface of a sphere, as shown in FIG. 7. FIG. 7 is a diagram showing various shapes of each of the metal particles or the acrylic material particles contained in the damping portion according to an embodiment of the present disclosure.

As shown in FIG. 6D and FIG. 7, the fourth damping portion 136d may be made of a flexible material such as rubber, and may contain 10% to 30% by weight of the metal particles or acrylic material particles therein. A content of the metal or acrylic material particles may be in a range of 10% to 30% by weight based on a total weight of the damping portion 136.

Each of the metal particles or acrylic material particles may have one of the shapes of a sphere, a hexahedron, a golf ball, or protrusions on a surface of a sphere, as shown in FIG. 7. Each of the metal particles or acrylic material particles may have a size of 1 mm×1 mm.

Referring to Table 1 below, a general head impact criterion HIC should meet a following condition: when a headform having a diameter of 165 mm and made of steel (STS), and having a weight 6.8 Kg, moves at a speed of 19 km/h and hits the display apparatus, the deceleration for a duration of 3 ms after the hit should not exceed a maximum of 80 g (HIC<80).

TABLE 1

| | Hitting condition |
|---|---|
| Velocity | Non Airbag: 24 km/h (15 MPH) |
| | Airbag: 19 km/h (11.8 MPH) |
| Impact range | 736 to 840 mm (29 to 33 in: based on SRP) |

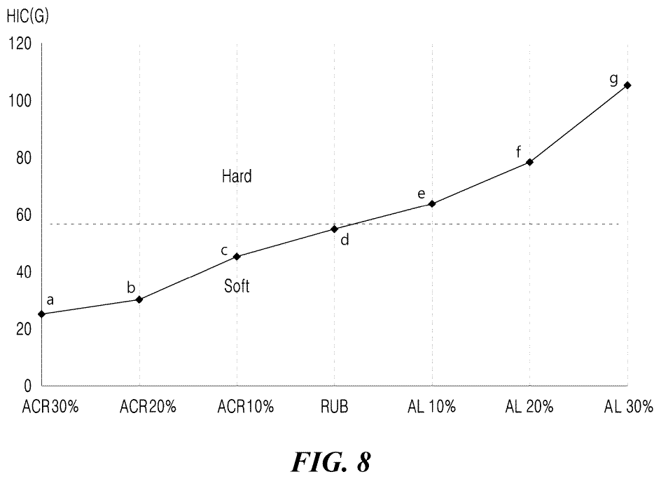

As shown in FIG. 8, in the mounting part 130 according to an embodiment of the present disclosure, the fourth damping portion 136d may be made of a mixture of acrylic ACR, aluminum AL or steel with the rubber material RUB. FIG. 8 is a graph showing the HIC value based on a content of the metal or acrylic material added to the damping portion according to an embodiment of the present disclosure. Referring to FIG. 8, the fourth damping portion 136d may be made of a mixture of aluminum AL or steel and rubber RUB. In FIG. 8, referring to Table 2 below, the G value of rubber RUB is 54.5(d). For example, the fourth damping portion 136d has a G value of 63.6(e) when 10% of aluminum AL (or steel) is added. Accordingly, the G value of the fourth damping portion 136d increases by 9.1 and the G value increases by 16.7% compared to when it is formed only of rubber. For example, the fourth damping portion 136d has a G value of 78(f) when 20% of aluminum AL is added. Accordingly, the G value of the fourth damping portion 136d increases by 24 and the G value increases by 44% compared to when it is formed only of rubber. For example, the fourth damping portion 136d has a G value of 105(g) when 30% of aluminum AL is added. Accordingly, the G value of the fourth damping portion 136d increases by 50.5 and the G value increases by 92.7% compared to when it is formed only of rubber. As mentioned above, the fourth damping portion 136d is made of a mixture of aluminum AL or steel with the rubber RUB in a mixing ration in a range of 10% to 30%, the G value of the HIC may be increase to a value in a range from 16.7% to 92.7%, which confirms that the G value increases compared to when only rubber is used.

TABLE 2

| | 10% | 20% | 30% |
|---|---|---|---|
| aluminum AL adding rate | | | |
| G value of rubber | 54.5 | 54.5 | 54.5 |
| increase(+)/decrease(−) of the G value | +9.1 | +24 | +50.5 |
| percentage of increase(+)/decrease(−) | +16.7% | +44.0% | +92.7% |
| acrylic ACR adding rate | | | |
| G value of rubber | 54.5 | 54.5 | 54.5 |
| increase(+)/decrease(−) of the G value | −9.5 | −24.5 | −29.5 |
| percentage of increase(+)/decrease(−) | −17.4% | −45.0% | −54.1% |

Furthermore, the fourth damping portion 136d may be made of the mixture of the rubber RUB and the acrylic material ACR, as shown in FIG. 8. For example, referring to Table 2 above, the fourth damping portion 136d has a G value of 45 (c) when 10% of acrylic ACR is added. Therefore, the G value of the fourth damping portion 136d decreases by 9.5 and the G value reduced by 17.4% compared to when it is formed only of rubber. For example, the fourth damping portion 136d has a G value of 30(b) when 20% of acrylic ACR is added. Therefore, the G value of the fourth damping portion 136d decreases by 24.5 and the G value reduced by 45% compared to when it is formed only of rubber. For example, the fourth damping portion 136d has a G value of 25(a) when 30% of acrylic ACR is added. Therefore, the G value of the fourth damping portion 136d decreases by 29.5 and the G value reduced by 54.1% compared to when it is formed only of rubber.

As described above, an impact absorbing amount of the fourth damping portion 136d according to an embodiment of the present disclosure may be controlled based on the content of the metal or the acrylic material.

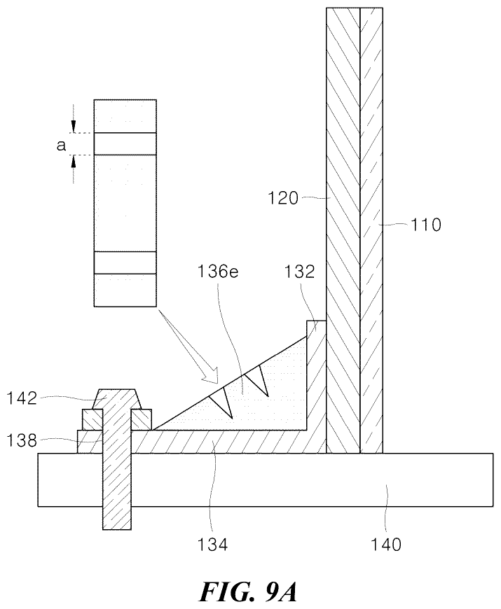

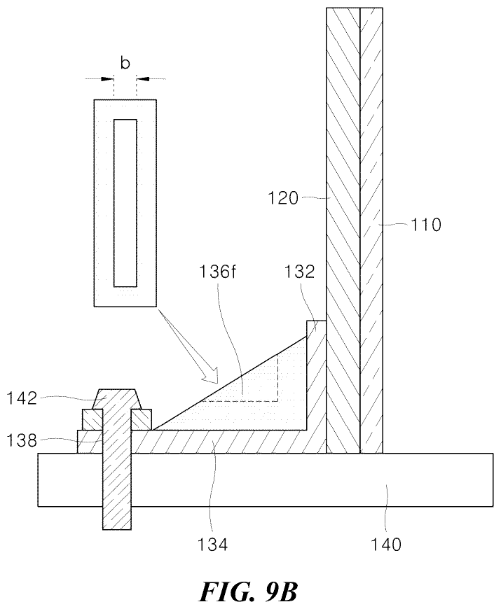

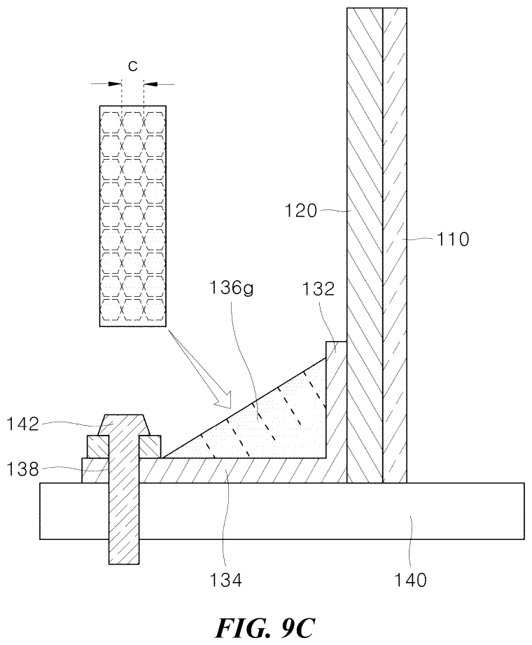

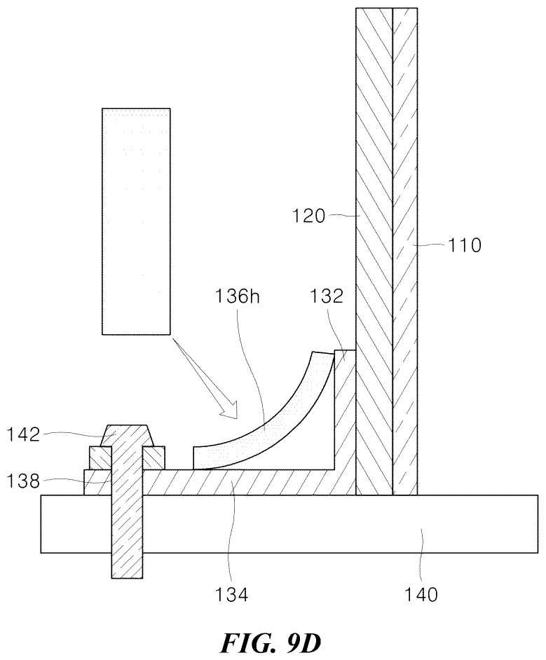

FIGS. 9A to 9D are diagrams showing various embodiments of the damping portion of the mounting part according to some further embodiments of the present disclosure.

Referring to FIG. 9A, the mounting part 130 according to another embodiment of the present disclosure may include a fifth damping portion 136e. The fifth damping portion 136e may be made of a flexible material such as rubber, and may have a flat bar shape or a rectangular shape in a plan view of the mounting part. The fifth damping portion 136e may have two through-holes defined therein. Each of the two through-holes has an empty space having a width a.

Accordingly, a cross-sectional shape of the fifth damping portion 136e may be a right triangle shape such that a right angle thereof corresponds to a right angle defined by the coupling portion 132 and the support portion 134 of the mounting part 130.

Accordingly, the two through-holes including the empty space may be formed in the fifth damping portion 136e. Thus, the fifth damping portion 136e may act as a damper in the event of a vehicle collision due to not only a nature of the rubber material but also presence of the two empty spaces.

Referring to FIG. 9B, the mounting part 130 according to still another embodiment of the present disclosure may include a sixth damping portion 136f. The sixth damping portion 136f may be made of a flexible material such as rubber, and may have a flat bar shape or a rectangular shape in a plan view of the mounting part, and may have an opening having a width b defined therein. As shown in FIG. 9B, in a plan view of the mounting part, the opening may be positioned in an inner area of the sixth damping portion 136f.

Accordingly, when an impact is applied to the back cover 120 during a vehicle collision, the sixth damping portion 136f absorbs the impact force due to the presence of the opening and serves as a buffer.

Referring to FIG. 9C, the mounting part 130 according to still another embodiment of the present disclosure may include a seventh damping portion 136g. The seventh damping portion 136g may be made of a flexible material such as rubber, and may have a flat bar shape or a rectangular shape in a plan view of the mounting part, and may have a plurality of through-holes with a maximum width c defined therein. In a plan view of the mounting part, the through-holes may be arranged in a matrix manner.

Accordingly, when the vehicle collides, the impact force may be absorbed by the plurality of through-holes defined in the seventh damping portion 136g of the mounting part 130. Thus, the seventh damping portion 136g serves as a buffer.

Referring to FIG. 9D, the mounting part 130 according to still yet another embodiment of the present disclosure may include an eighth damping portion 136h. The eighth damping portion 136h may be made of a flexible material such as rubber, and may have a flat bar shape or a rectangular shape in a plan view of the mounting part. The eighth damping portion 136h may be bent convexly toward a contact point of the coupling portion 132 as a vertical portion and the support portion 134 as a horizontal portion as upper and lower ends of the eighth damping portion 136h come into contact with the coupling portion 132 as the vertical portion and the support portion 134 as the horizontal portion, respectively.

Accordingly, when an impact is applied to the back cover 120 during a vehicle collision, the impact force may be absorbed due to the bent shape of the seventh damping portion 136g of the mounting part 130. Thus, the seventh damping portion 136g serves as a buffer.

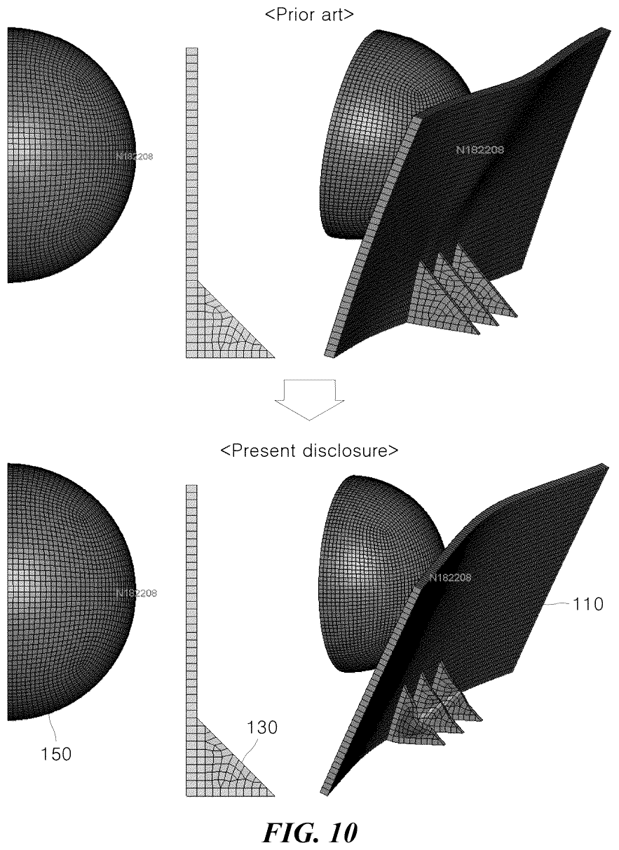

As described above, the mounting part 130 according to an embodiment of the present disclosure may have at least one of the first damping portion 136a to the eighth damping portion 136g. Thus, as shown in FIG. 10 during a vehicle collision, even when an impact is applied to the display apparatus 100, the impact may be absorbed by the damping portion 136 having at least one of the structures of the first damping portion 136a to the eighth damping portion 136g. Thus, the head injuries to the driver or the passengers may be prevented.

FIG. 10 is a diagram showing an example of absorbing a shock when the shock is applied to a display apparatus according to an embodiment of the present disclosure.

As shown in FIG. 10, when an impact body 150 made of steel STS, weighing 6.8 Kg, and having a diameter of 165 mm moves at a speed of 19 Km/h and hits the display apparatus 100 according to an embodiment of the present disclosure, the deceleration for a duration of 3 ms after the hitting does not exceed a maximum of 80 g due to the presence of the mounting part 130 including the damping portion 136.

Therefore, when the display apparatus 100 according to an embodiment of the present disclosure mounted on the vehicle, the display apparatus 100 satisfies the head impact criterion (HIC) under the regulation, thereby minimizing or preventing injuries to drivers or passengers even in the event of a vehicle collision.

As described above, according to an embodiment of the present disclosure, the display apparatus mounted on the vehicle may be provided. The display apparatus may have a structure in which the back cover coupled to the cover glass module including the display panel is fixed to the dashboard through the mounting part made of the flexible rubber.

Furthermore, the display apparatus according to an embodiment of the present disclosure comprising: the cover glass module includes the display panel, the scan driver supplies the scan signal to the display panel, the data driver supplies the data voltage to the display panel, the timing controller controls the gate driver and the data driver, the power supply supplies a high power voltage, a low power voltage, and an initialization voltage to the display panel, the back cover is coupled to the cover glass module to support the cover glass module, and the mounting part fixes the back cover, wherein the mounting part may include the damping portion made of the mixture of rubber and metal or the mixture of rubber and acrylic material.

A display apparatus according to some aspects and embodiments of the present disclosure may be described as follows.

A first aspect of the present disclosure provides a display apparatus comprising: a cover glass module including a display panel; a back cover coupled to the cover glass module so as to support the cover glass module; and a mounting part for fixing the back cover.

In accordance with the display apparatus of the first aspect, the mounting part includes: a coupling portion coupled to the back cover; a support portion for supporting the coupling portion; and a damping portion for absorbing shock applied to the back cover.

In accordance with the display apparatus of the first aspect, the damping portion is made of a rubber material.

In accordance with the display apparatus of the first aspect, the damping portion is made of a mixture of rubber and metal.

In accordance with the display apparatus of the first aspect, the metal includes aluminum (Al) or steel.

In accordance with the display apparatus of the first aspect, the aluminum or the steel accounts for 10% to 30% of the content of the damping portion.

In accordance with the display apparatus of the first aspect, the damping portion is made of a mixture of rubber and acrylic material.

In accordance with the display apparatus of the first aspect, the acrylic material accounts for 10% to 30% of the content of the damping portion.

In accordance with the display apparatus of the first aspect, the back cover is coupled to the mounting part through a connection portion having a shock-absorbing space defined therein.

A second aspect of the present disclosure provides a display apparatus comprising: a cover glass module including a display panel; a scan driver configured to supply a scan signal to the display panel; a data driver configured to supply a data voltage to the display panel; a timing controller configured to control the scan driver and the data driver; a power supply configured to provide a high power voltage, a low power voltage, and an initialization voltage to the display panel; a back cover coupled to the cover glass module so as to support the cover glass module; and a mounting part for fixing the back cover, wherein the mounting part includes a damping portion made of a mixture of rubber and metal or a mixture of rubber and acrylic material.

In accordance with the display apparatus of the second aspect, the display panel includes a display area, a non-display area and a bent area.

In accordance with the display apparatus of the second aspect, an optical control layer is disposed on top of the display panel and is bonded to the display panel through a first adhesive layer, wherein a cover member is disposed on the optical control layer and is bonded to the optical control layer through an optical adhesive layer, wherein a first support member is disposed under the display panel and is bonded to the display panel through a second adhesive layer, wherein a plate is disposed under the first support member and is bonded to the first support member through a third adhesive layer, wherein a connection member is disposed under the plate and is bonded to the plate through a fourth adhesive layer, wherein a second support member is disposed under the connection member and is bonded to the connection member through a fifth adhesive layer, wherein a pad and a bent portion of the display panel are disposed under the second support member, wherein a bent reinforcement member is disposed under the bent portion of the display panel, and wherein the reinforcement member is disposed on an outer surface of the display panel in the bent area to reinforce bending of the display panel.

In accordance with the display apparatus of the second aspect, the optical control layer includes a polarizing layer, wherein the reinforcement member includes a micro coating layer.

In accordance with the display apparatus of the second aspect, the bent area has an inner area inwardly of the bent portion of the display panel, and wherein the inner area is filled with a resin including an organic insulating material.

In accordance with the display apparatus of the second aspect, the connection member fixes a bent state of a bezel and includes a foam tape, a foam pad, a tape with a shock absorbing function or a double-sided tape with conductivity.

In accordance with the display apparatus of the second aspect, the connection member is composed of at least one layer made of at least one of an optical clear adhesive (OCA), an optical clear resin (OCR), or a pressure sensitive adhesive (PSA).

In accordance with the display apparatus of the second aspect, the plate is made of a plastic material including at least one of polycarbonate (PC), polyimide (PI), polyethylene naphthalate (PEN), and polyethylene terephthalate (PET).

In accordance with the display apparatus of the second aspect, each of the first and second support members includes one of stainless steel (SUS), glass, ceramic, and metal, or a combination thereof.

In accordance with the display apparatus of the second aspect, the metal or the acrylic material accounts for 10% to 30% of the content of the damping portion.

In accordance with the display apparatus of the first aspect or the second aspect, the damping portion has a through-hole, a groove, or an opening defined therein.

In accordance with the display apparatus of the first aspect or the second aspect, the damping portion has a horizontal portion and a vertical portion.

In accordance with the display apparatus of the first aspect or the second aspect, the damping portion has a middle portion bent convexly toward a side thereof.

A third aspect of the present disclosure provides a vehicle comprising: a display apparatus of the first aspect or the second aspect; and a dashboard on which the display apparatus is mounted.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a cover glass module including a display panel;
a back cover coupled to the cover glass module and configured to support the cover glass module; and
a mounting part configured to fix the back cover to a support of a vehicle.

2. The display apparatus of claim 1, wherein the mounting part includes:
a coupling portion coupled to the back cover;
a support portion configured to support the coupling portion; and
a damping portion configured to absorb shock applied to the back cover.

3. The display apparatus of claim 2, wherein the damping portion is made of a rubber material.

4. The display apparatus of claim 2, wherein the damping portion is made of a mixture of rubber and metal.

5. The display apparatus of claim 4, wherein the metal includes aluminum (Al) or steel.

6. The display apparatus of claim 5, wherein the aluminum or the steel is 10% to 30% of a weight of the damping portion.

7. The display apparatus of claim 2, wherein the damping portion is made of a mixture of rubber and acrylic material.

8. The display apparatus of claim 7, wherein the acrylic material is 10% to 30% of a weight of the damping portion.

9. The display apparatus of claim 1, wherein the back cover is coupled to the mounting part through a connection portion, the connection portion having a shock-absorbing space.

10. A display apparatus, comprising:
a cover glass module including a display panel;
a scan driver configured to supply a scan signal to the display panel;
a data driver configured to supply a data voltage to the display panel;
a timing controller configured to control the scan driver and the data driver;
a power supply configured to provide a high power voltage, a low power voltage, and an initialization voltage to the display panel;
a back cover coupled to the cover glass module, the back cover configured to support the cover glass module; and
a mounting part configured to fix the back cover to a support of a vehicle,
wherein the mounting part includes a damping portion made of a mixture of rubber and metal or a mixture of rubber and acrylic material.

11. The display apparatus of claim 10, wherein the display panel includes a display area, a non-display area and a bent area,
wherein an optical control layer is disposed on the display panel and is bonded to the display panel through a first adhesive layer,
wherein a cover member is disposed on the optical control layer and is bonded to the optical control layer through an optical adhesive layer,
wherein a first support member is disposed under the display panel and is bonded to the display panel through a second adhesive layer,
wherein a plate is disposed under the first support member and is bonded to the first support member through a third adhesive layer,
wherein a connection member is disposed under the plate and is bonded to the plate through a fourth adhesive layer,
wherein a second support member is disposed under the connection member and is bonded to the connection member through a fifth adhesive layer,
wherein a pad and a bent portion of the display panel are disposed under the second support member,
wherein a reinforcement member is disposed under the bent portion of the display panel, and
wherein the reinforcement member is disposed on an outer surface of the display panel in the bent area and configured to reinforce bending of the display panel.

12. The display apparatus of claim 11, wherein the optical control layer includes a polarizing layer, and
wherein the reinforcement member includes a micro coating layer.

13. The display apparatus of claim 11, wherein the bent area has an inner area positioned inward of the bent portion of the display panel relative to the display panel, and
wherein the inner area is filled with a resin including an organic insulating material.

14. The display apparatus of claim 11, wherein the connection member fixes a bezel in a bent state and includes a foam tape, a foam pad, a tape with a shock absorbing function or a double-sided tape with conductivity.

15. The display apparatus of claim 11, wherein the connection member includes at least one layer made of at least one of an optical clear adhesive (OCA), an optical clear resin (OCR), or a pressure sensitive adhesive (PSA).

16. The display apparatus of claim 11, wherein the plate is made of a plastic material including at least one of polycarbonate (PC), polyimide (PI), polyethylene naphthalate (PEN), and polyethylene terephthalate (PET).

17. The display apparatus of claim 11, wherein each of the first and second support members includes one of stainless steel (SUS), glass, ceramic, and metal, or a combination thereof.

18. The display apparatus of claim 10, wherein the metal or the acrylic material is 10% to 30% of a weight of the damping portion.

19. The display apparatus of claim 10, wherein the damping portion has a through-hole, a groove, or an opening.

20. The display apparatus of claim 10, wherein the damping portion has a horizontal portion and a vertical portion.

21. The display apparatus of claim 10, wherein the damping portion has a middle portion bent convexly toward a side of the damping portion.

22. A vehicle, comprising:
a display apparatus, including:
a cover glass module including a display panel;
a back cover coupled to the cover glass module and configured to support the cover glass module; and
a mounting part; and
a dashboard, the mounting part coupled to the dashboard to mount the display apparatus on the dashboard.
